(19) United States
(12) Patent Application Publication
(10) Pub. No.: US 2005/0245004 A1
(43) Pub. Date: Nov. 3, 2005

(54) Method for manufacturing wiring substrate and method for manufacturing electronic device

(76) Inventors: Satoshi Kimura, Nagano-Ken (JP); Hidemichi Furihata, Chino-shi (JP); Minoru Marumo, Nagano-Ken (JP)

Correspondence Address: HARNESS, DICKEY & PIERCE, P.L.C., P.O. BOX 828, BLOOMFIELD HILLS, MI, 48303, US

(21) Appl. No.: 11/050,255

(22) Filed: Feb. 3, 2005

(30) Foreign Application Priority Data
Feb. 4, 2004 (JP) 2004-028117

(51) Int. Cl. H01L 21/48

(52) U.S. Cl. 438/125; 438/674; 29/850

(57) ABSTRACT

A method for manufacturing a wiring substrate includes the steps of (a) providing a surface-active agent in first and second areas of a substrate, (b) irradiating a vacuum ultraviolet radiation to the second area of the substrate to thereby break down an interatomic bond in the second area of the substrate, (c) washing the substrate to thereby remove a portion of the surface-active agent in the second area, (d) providing a catalyst on an area of the surface-active agent remaining in the first area, and (e) depositing a metal layer to the catalyst to thereby form a wiring composed of the metal layer along the first area.

### RELATED APPLICATIONS

This application claims priority to Japanese Patent Application No. 2004-028117 filed Feb. 4, 2004 which is hereby expressly incorporated by reference herein in its entirety.

### BACKGROUND

1. Technical Field

The present invention relates to a method for manufacturing wiring substrates and a method for manufacturing electronic devices.

2. Related Art

A subtractive method and an additive method are known as a method for forming wirings on a flexible substrate. In the subtractive method, a metal layer is formed over the entire surface of a flexible substrate, a photoresist is formed on the metal layer by patterning, and the metal layer is etched by using the photoresist as a barrier. In the additive method, a photoresist is formed on a flexible substrate by patterning, and a metal layer is deposited by a plating process in an opening section in the photoresist.

These methods entail problems concerning consumptions of resources and raw material, in view of the fact that the photoresist is finally removed, and further in view of the fact that a part of the metal layer is removed in the subtractive method. Also, they require the steps of forming and removing a photoresist, which results in a problem of a large number of manufacturing steps. Furthermore, because the measurement accuracy of wirings depends on the resolution of a photoresist, there is a limit in forming wirings at a higher level of accuracy.

It is an object of the present invention to deposit a metal layer only in a required portion, and form wirings with a simple manufacturing process.

### SUMMARY

A method for manufacturing a wiring substrate in accordance with the present invention includes the steps of
(a) providing a surface-active agent in first and second areas of a substrate;
(b) irradiating a vacuum ultraviolet radiation to the second area of the substrate to thereby break down an interatomic bond in the second area of the substrate;
(c) washing the substrate to thereby remove a portion of the surface-active agent provided in the second area;
(d) providing a catalyst on an area of the surface-active agent remaining in the first area; and
(e) depositing a metal layer on the catalyst to thereby form a wiring composed of the metal layer along the first area.

According to the present invention, the surface-active agent is patterned by irradiation of a vacuum ultraviolet radiation, and the catalyst is provided on the surface-active agent. By this, a metal layer can be precipitated only on a required portion along a predetermined pattern configuration. Accordingly, for example, there is no need to form a mask with a resist layer, and a waste of material can be reduced, and highly accurate wirings can be formed at a low cost with a simple and short-time manufacturing process.

A method for manufacturing a wiring substrate in accordance with the present invention includes the steps of:
(a) providing a surface-active agent in first and second areas of a substrate;
(b) irradiating a vacuum ultraviolet radiation to the second area of the substrate to thereby break down an interatomic bond in the second area of the substrate;
(c) washing the substrate to thereby remove a portion of the surface-active agent provided in the second area;
(d) providing a catalyst in the second area of the substrate; and
(e) depositing a metal layer on the catalyst to thereby form a wiring composed of the metal layer along the second area.

According to the present invention, the surface-active agent is patterned by irradiation of a vacuum ultraviolet radiation, and the catalyst is provided on the surface-active agent. By this, a metal layer can be precipitated only on a required portion along a predetermined pattern configuration. Accordingly, for example, there is no need to form a mask with a resist layer, and a waste of material can be reduced, and highly accurate wirings can be formed at a low cost with a simple and short-time manufacturing process.

In the method for manufacturing a wiring substrate, the substrate may have at least one of a C—C, C═C, C—F, C—H, C—Cl, C—N, C—O, N—H and O—H bond.

In the method for manufacturing a wiring substrate, the substrate may have at least a C═C bond, and the vacuum ultraviolet radiation may have at least a property that can break down the C═C bond.

In the method for manufacturing a wiring substrate, a light source of the vacuum ultraviolet radiation may be an excimer lamp having Xe gas enclosed therein.

A method for manufacturing a wiring substrate in accordance with the present invention includes the steps of:
(a) providing a surface-active agent by using a droplet discharge method on a first area of a substrate having the first area and a second area;
(b) providing a catalyst on the surface-active agent; and
(c) depositing a metal layer on the catalyst to thereby form a wiring composed of the metal layer along the first area.

According to the present embodiment, the surface-active agent is patterned by using a droplet discharge method, and the catalyst is provided on the surface-active agent. By this, a metal layer can be precipitated only on a required portion along a predetermined pattern configuration. Accordingly, for example, there is no need to form a mask with a resist layer, and a waste of material can be reduced, and highly accurate wirings can be formed at a low cost with a simple and short-time manufacturing process.

A method for manufacturing a wiring substrate in accordance with the present invention includes the steps of
(a) providing a surface-active agent by using a droplet discharge method on a first area of a substrate having the first area and a second area;
(b) providing a catalyst on the second area of the substrate; and
(c) depositing a metal layer on the catalyst to thereby form a wiring composed of the metal layer along the second area.

According to the present embodiment, the surface-active agent is patterned by using a droplet discharge method, and the catalyst is provided on the surface-active agent. By this, a metal layer can be precipitated only on a required portion along a predetermined pattern configuration. Accordingly, for example, there is no need to form a mask with a resist layer, and a waste of material can be reduced, and highly accurate wirings can be formed at a low cost with a simple and short-time manufacturing process.

In the method for manufacturing a wiring substrate, the droplet discharge method may be an ink jet method. According to this, by applying the technology that has been put in practice for ink jet printers, ink can be economically provided at a high speed without a waste.

In the method for manufacturing a wiring substrate, a surface potential of the first and second areas of the substrate may be a negative potential.

In the method for manufacturing a wiring substrate, before the step (b), the step of washing the substrate with an alkali may be further included. According to this, potential nonuniformity of the substrate surface can be made uniform by washing the substrate with an alkali, such that the surface potential can be stabilized with a simple manufacturing process.

In the method for manufacturing a wiring substrate, in the step (a), a cationic system surface-active agent may be used as the surface-active agent.

In the method for manufacturing a wiring substrate, in the step of providing the catalyst, the substrate may be dipped in a solution including tin chloride, and then dipped in a catalyst liquid including palladium chloride, to thereby deposit palladium as the catalyst.

In the method for manufacturing a wiring substrate, in the step of providing the catalyst, the substrate may be dipped in a catalyst liquid including tin-palladium to remove tin from the substrate, to thereby deposit palladium as the catalyst.

A method for manufacturing an electronic device in accordance with the present invention includes: the method for manufacturing a wiring substrate described above, and further includes the steps of mounting a semiconductor chip having an integrated circuit on the wiring substrate, and electrically connecting the wiring substrate to a circuit substrate. According to the present invention, a waste of material can be reduced, and highly accurate wirings can be formed at a low cost with a simple and short-time manufacturing process.

### BRIEF DESCRIPTION OF THE DRAWINGS

FIG. 1 (A)-FIG. 1 (C) are views illustrating a first example of a first embodiment of the present invention.

FIG. 2 (A) and FIG. 2 (B) are views illustrating the first example of the first embodiment of the present invention.

FIG. 3 (A)-FIG. 3 (D) are views illustrating the first example of the first embodiment of the present invention.

FIG. 4 (A) and FIG. 4 (B) are views illustrating the first example of the first embodiment of the present invention.

FIG. 5 (A) and FIG. 5 (B) are views illustrating a second example of the first embodiment of the present invention.

FIG. 6 (A) and FIG. 6 (B) are views illustrating a first example of a second embodiment of the present invention.

FIG. 7 (A) and FIG. 7 (B) are views illustrating the first example of the second embodiment of the present invention.

FIG. 8 (A)-FIG. 8 (C) are views illustrating the first example of the second embodiment of the present invention.

FIG. 9 (A) and FIG. 9 (B) are views illustrating the first example of the second embodiment of the present invention.

FIG. 10 (A) and FIG. 10 (B) are views illustrating a second example of the second embodiment of the present invention.

FIG. 11 is a view illustrating a third embodiment of the present invention.

### DETAILED DESCRIPTION

Embodiments of the present invention are described below with reference to the accompanying drawings.

### First Embodiment

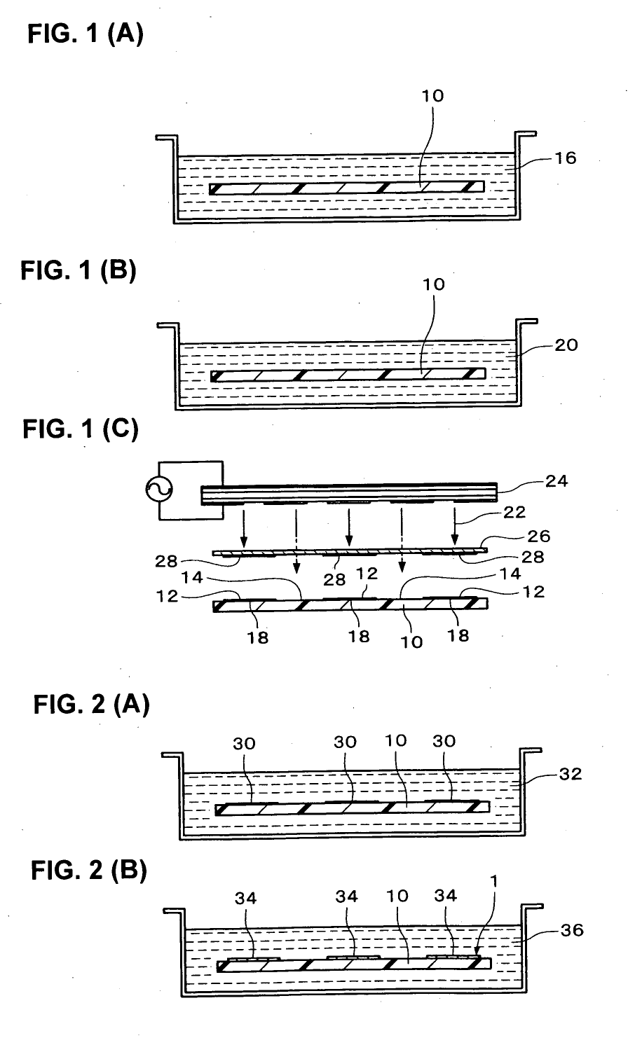

FIG. 1 (A)-FIG. 11 (B) are views illustrating a method for manufacturing a wiring substrate in accordance with a first embodiment of the present invention. In the present embodiment, a wiring substrate is manufactured using an electroless plating method.

### FIRST EXAMPLE

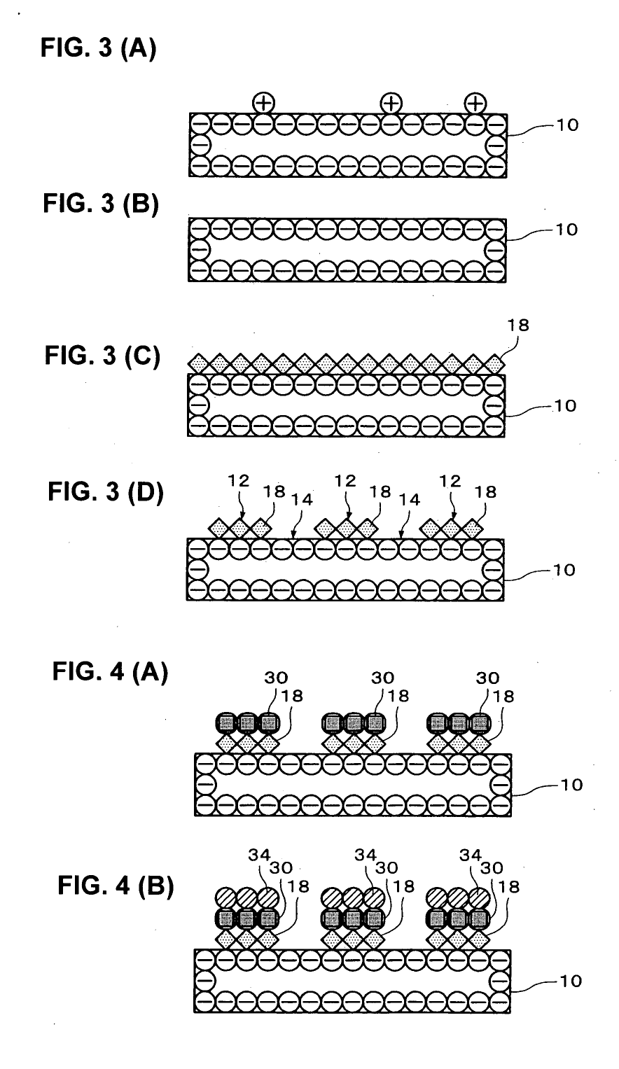

FIG. 1 (A)-FIG. 4 (B) are views illustrating a first example of the present embodiment. FIG. 1 (A)-FIG. 2 (B) are views for describing steps of the electroless plating method, and FIG. 3 (A)-FIG. 4 (B) are views schematically illustrating a substrate in each of the steps of the electroless plating method.

A substrate (sheet) 10 may be a flexible substrate. As the flexible substrate, a FPC (Flexible Printed Circuit), a COF (Chip On Film) substrate, or a TAB (Tape Automated Bonding) substrate may be used. The substrate 10 is formed from an organic material (for example, resin). As the substrate 10, a polyimide substrate or a polyester substrate may be used. The substrate 10 has an organic interatomic bond. The substrate 10 may have at least one of a C—C, C═C, C—F, C—H, C—Cl, C—N, C—O, N—H and O—H bond. The substrate 10 may have at least a C═C bond. In the present embodiment, a wiring is formed on one of surfaces of the substrate 10. Alternatively, wirings may be formed on both of the surfaces of the substrate 10. The substrate 10 has first and second areas 12 and 14 (see FIG. 1 (C) and FIG. 3 (D)). The first and second areas 12 and 14 are areas in the surface of the substrate 10 where wirings are formed.

As shown in FIG. 3 (A), a substrate whose surface potential (a surface potential in liquid) is a negative potential may be used as the substrate 10. In the case of an organic system material, the surface potential of the substrate 10 is often a negative potential.

As shown in FIG. 1 (A) and FIG. 3 (B), the substrate 10 may be washed with an alkali. By so doing, nonuniformity of the surface potential of the first and second areas 12 and 14 of the substrate 10 can be made uniform into a negative potential. More specifically, the substrate 10 may be dipped in an alkaline solution (for example, a sodium hydroxide in a concentration of 1 wt %-10 wt %) 16 at room temperature for about 10 minutes-60 minutes, and then washed with clean water. If a surface layer portion of the substrate 10 is hydrolyzed by the alkali washing, the surface layer portion becomes a hydrolyzed layer. Because the surface layer portion is also at a negative potential, its potential becomes more uniform than it was before the washing.

It is noted that cleaning and surface roughening treatment of the substrate 10 can be conducted at the same time by the above-described alkali washing. By this, the adhesion of a metal layer (wiring) can be improved.

As shown in FIG. 1 (B) and FIG. 3 (C), a surface active agent 18 is provided in the first and second areas 12 and 14 of the substrate 10. The surface-active agent 18 may be provided over the entire area of one of the surfaces of the substrate 10. In the present example, the surface-active agent 18 has a property to form positive ion. As the surface-active agent 18, a cationic system surface-active agent (a cation surface-active agent or one having a property equal to the same) may be used. In the present example, because the surface potential of the first and second areas 12 and 14 of the substrate 10 is a negative potential, the negative potential on the surface of the substrate 10 can be neutralized or reversed to a positive potential by the cationic system surface-active agent used. It is noted that, by the use of the surface-active agent, the surface potential can be freely adjusted without depending on the property of the substrate 10, and the surface potential can be made uniform such that a stable potential surface can be formed.

In the example shown in FIG. 1 (B), the substrate 10 is dipped in a surface-active agent solution 20. More specifically, the substrate 10 is dipped in a cation surface-active agent solution of an alkyl ammonium chloride system at room temperature for about 1-10 minutes, and then washed with pure water. Then, the substrate 10 is placed in a room temperature atmosphere, and sufficiently dried.

As shown in FIG. 1 (C) and FIG. 3 (D), portions of the surface-active agent 18 provided in the second area 14 among the first and second areas 12 and 14 are removed. In other words, the surface-active agent 18 is patterned in a manner to remain along the first region 12.

In the present example, a vacuum ultraviolet radiation (VUV; vacuum ultraviolet radiation) 22 is irradiated to the second area 14 of the substrate 10. More specifically, a mask 26 is disposed between a source of light 24 and the substrate 10, and the vacuum ultraviolet radiation 22 is irradiated to the substrate 10 through the mask 26. The vacuum ultraviolet radiation 22 is covered by a pattern 28 of the mask 26 and penetrates other areas. When the vacuum ultraviolet radiation 22 is irradiated, the interatomic bond in the second area 14 of the substrate 10 is (chemically) broken down. In the present example, the second area 14 of the substrate 10 is not mechanically cut. According to this method, the vacuum ultraviolet radiation 22 is used mainly for the action of breaking the interatomic bond of the substrate 10, such that its energy consumption can be lowered compared with the case of cutting the substrate 10. As a result, for example, a heat distortion can be prevented from being generated in the substrate 10. Moreover, the method can prevent a part of the substrate 10 from dispersing and adhering to other parts.

It is noted here that, in the present example, the first area 12 is an area where a metal layer (wiring) is formed, and has a predetermined pattern configuration. The second area 14 has a reversed configuration of the first area 12 in the surface of the substrate 10.

The vacuum ultraviolet radiation 22 may have a wavelength of 100 nm-200 nm (for example, 100 nm-180 nm). The vacuum ultraviolet radiation 22 has a property (for example, a wavelength) that can break down the organic interatomic bond. The vacuum ultraviolet radiation 22 may have a property (for example, a wavelength) that can break down at least a C═C bond of the substrate 10. It may have a property (for example, a wavelength) that can break down all of the interatomic bonds (composed of at least one of a C—C, C═C, C—F, C—H, C—Cl or C—N C—O, N—H and O—H bond) of the substrate 10. An excimer lamp enclosing Xe gas therein may be used as the source of light 24 (with a wavelength of 172 nm). Because a condenser lens for laser generation and the scanning time with a laser become unnecessary if the lamp is used, simplification of the manufacturing process can be achieved.

More specifically, a mask 26 is arranged over a wiring forming surface of the substrate 10, as shown in FIG. 1 (C). The mask 26 may be a photomask, or may be a metal mask. For example, a high-purity silica glass for vacuum ultraviolet radiation (with a transmittance of vacuum ultraviolet radiation of 80% or more) having a pattern formed with chrome is used as the mask 26. Although the mask 26 is shown to be spaced from and above the substrate 10 in FIG. 1 (C), the mask 26 is actually disposed on and in contact with the substrate 10. The source of light 24, the mask 26, and the substrate 10 are disposed in a nitrogen atmosphere. The vacuum ultraviolet radiation 26 is irradiated up to the distance of about 10 mm without attenuating in the nitrogen atmosphere.

When neither the substrate 10 nor the mask 26 comes in contact uniformly due to an elasticity and/or a warp of the substrate 10, an outer circumference portion of the mask 26 may be retained with a holder, and the back of the substrate 10 may be pressed toward the mask 26 side in an area of the same size as the mask 26. The source of light 24 is placed close to the substrate 10 as much as possible (for example, 10 mm or less). For example, as the source of light 24, an excimer VUV/03 Cleaning Unit (Manufacturer name; Ushio Electric Co., Model; UER20-172A/B, and Lamp specification; Dielectric barrier discharge excimer lamp enclosing Xe gas therein) may be used. When the raw material of the substrate 10 consists of polyimide, the output is adjusted to about 10 mW and irradiation is conducted for about ten minutes. The vacuum ultraviolet radiation 22 is irradiated to one of the surfaces of the substrate 10 in the present example. However, when wirings are to be formed on both sides of the substrate 10, the vacuum ultraviolet radiation 22 may be irradiated to each of the faces of the substrate 10 one by one or to both of them at the same time.

After irradiation of the vacuum ultraviolet radiation 22, the substrate 10 is washed (for example, by wet washing). By so doing, portions in the substrate 10 where the interatomic bond is dissolved are removed. In other words, by washing, the surface-active agent 18 on the second area 14 is removed. As the washing method, the substrate 10 may be dipped in a washing solution, or a shower thereof may be jetted to the substrate 10. An alkaline solution (a strong alkaline solution or a weak alkaline solution) or pure water may be used as the washing solution. Shower washing with pure water or high-pressure jet washing with pure water may be applied as the shower method. Supersonic vibration may be added at the time of washing. By washing, the surface-active agent 18 remains in the first area 12, and the surface-active agent 18 in the second area 14 is removed such that the surface of the substrate 10 is exposed.

As shown in FIG. 2 (A) and FIG. 4 (A), a catalyst (plating catalyst) 30 is provided on a portion of the surface-active agent 18 remaining in the first area 12. The catalyst 30 causes the precipitation of a metal layer (plating layer) in an electroless plating liquid, and may be, for example, palladium. A resin for bonding may not be included in the catalyst 30. In the present example, the catalyst 30 is not provided in the second area 14.

In the example shown in FIG. 2 (A), the substrate 10 is dipped in a catalyst liquid 32 including tin-palladium. More specifically, the substrate 10 is dipped in a tin-palladium colloid catalyst liquid of approximately PH1 for 30 seconds-three minutes at room temperature, and then sufficiently washed with clear water. Tin-palladium colloidal particle has a negative charge, and is adsorbed to the surface-active agent 18 (cationic system surface-active agent). Then, the substrate 10 is dipped in a solution including a fluoroborate acid at room temperature for 30 seconds three minutes for activation of the catalyst, and then washed with clear water. As a result, the tin colloidal particle is removed, and palladium alone can be precipitated on the surface-active agent 18 (cationic system surface-active agent).

As shown in FIG. 2 (B) and FIG. 4 (B), a metal layer 34 is precipitated to the catalyst 30. Because the catalyst 30 is provided on the surface-active agent 18, and the surface-active agent 18 is exposed along the first area 12, the metal layer 34 can be formed in a pattern configuration along the first area 12. The metal layer 34 may be formed with one layer, or may be formed with multiple layers. The material of the metal layer 34 is not limited, and may be, for example, any one of Ni, Au, Ni+Au, Cu, Ni+Cu and Ni+Au+Cu. A catalyst may be selected according to the material of the metal layer 36 to be deposited.

In the example shown in FIG. 2 (B), the substrate 10 is dipped in a plating solution 36 mainly containing nickel sulfate hexahydrate (at a temperature of 80° C.) for about one minute-three minutes, to form a nickel layer having a thickness of about 0.1-0.2 μm. Alternatively, the substrate 10 may be dipped in a plating solution mainly containing nickel chloride hexahydrate (at a temperature of 60° C.) for about three minutes ten minutes, to form a nickel layer having a thickness of about 0.1-0.2 μm. According to the present example, because the catalyst 30 is provided along the first area 12, the metal layer 34 can be selectively formed along the first area 12 of the substrate 10 even without forming a mask with a resist layer or the like.

In accordance with the present example, the surface-active agent 18 is patterned by irradiating the vacuum ultraviolet radiation 22, and the catalyst 30 is provided on the surface-active agent 18. As a result, the metal layer 34 can be deposited only on a required portion along a predetermined pattern configuration. Therefore, for example, there is no need to form a mask with a resist layer or the like, and a waste of material can be reduced, and wirings can be formed at a low cost with high accuracy, with a simple and short-time manufacturing process.

### SECOND EXAMPLE

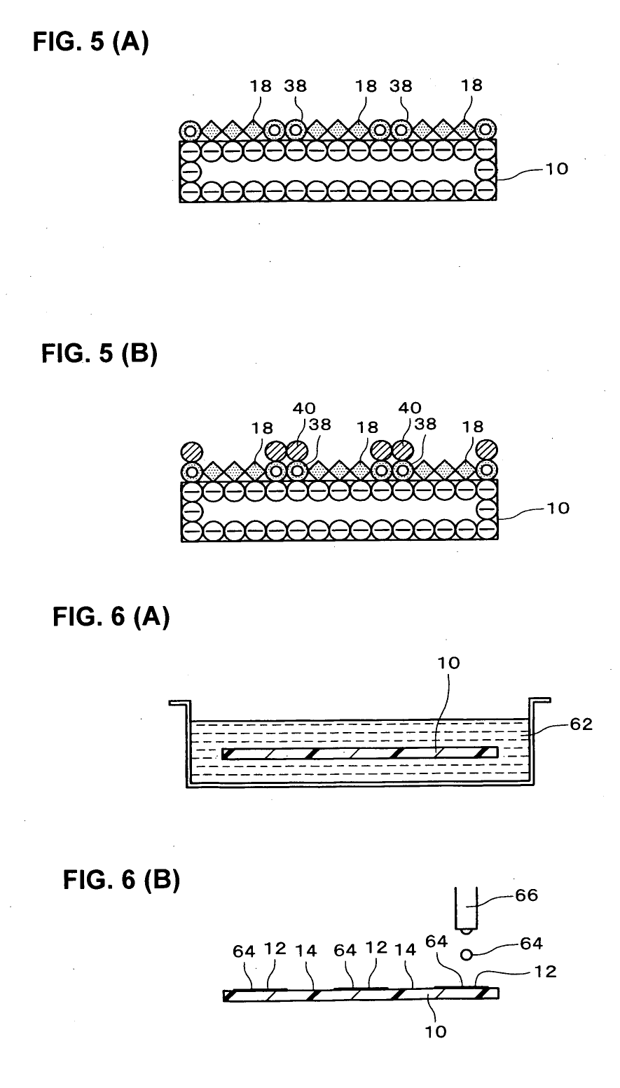

FIG. 5 (A) and FIG. 5 (B) are views illustrating a second example of the present embodiment. In the present example, after a surface-active agent 18 has been provided in a first area 12, as indicated in FIG. 3 (A)-FIG. 3 (D), a catalyst 38 is provided in a second area 14 of the substrate 10. In other words, the catalyst 38 is provided in the second area 14 of the surface of the substrate 10, which is exposed through the surface-active agent 18. In the present example, the second area 14 is an area where a metal layer (wiring) is formed, and has a predetermined pattern configuration.

For example, the substrate 10 is dipped in a solution including tin chloride having a positive charge, and then dipped in a catalyst liquid including palladium chloride, such that palladium can be precipitated to the second area 14 (portion having a negative potential) of the substrate. It is noted that the substrate 10 may be dipped in the catalyst liquid for one minute-five minutes, and then washed with pure water.

Then, as shown in FIG. 5 (B), a metal layer 40 is precipitated to the catalyst 38. Because the catalyst 38 is provided on the second area 14, the metal layer 40 can be formed in a pattern configuration along the second area 14.

It is noted that the details described above in the aforementioned example can be applied to other details of the present example.

### Second Embodiment

FIG. 6 (A)-FIG. 10 (B) are views illustrating a method for manufacturing a wiring substrate in accordance with a second embodiment of the present invention. It the present embodiment, a surface-active agent is patterned by using a droplet discharge method.

### FIRST EXAMPLE

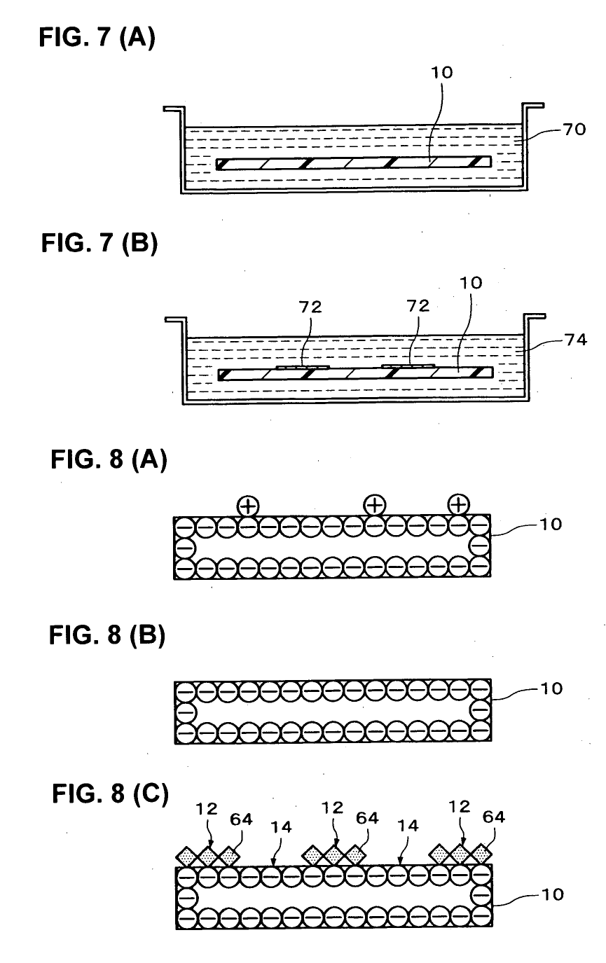

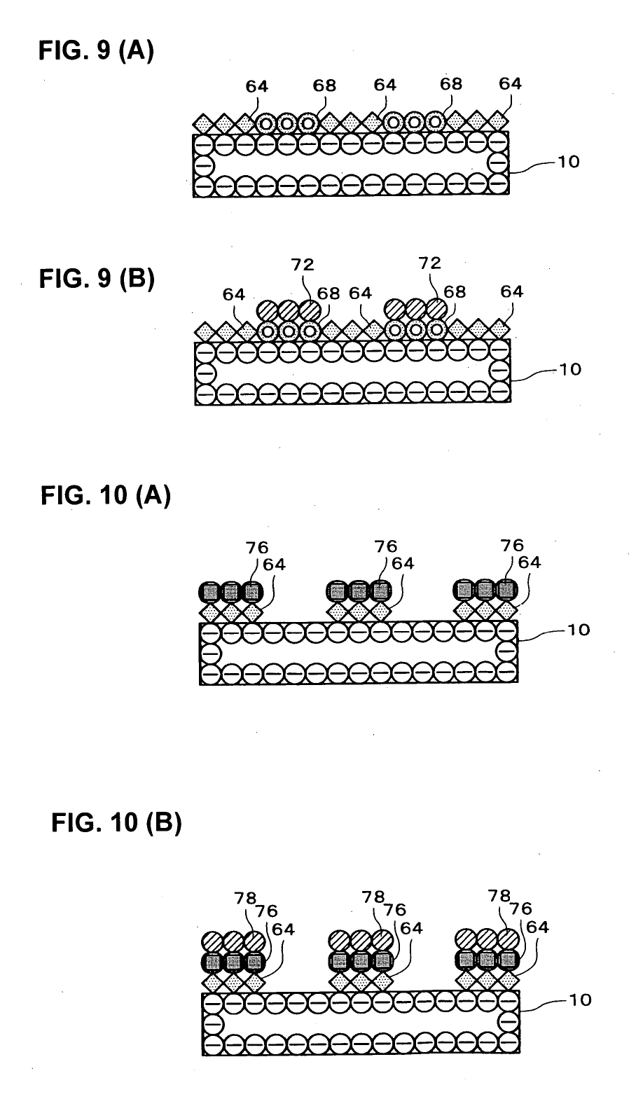

FIG. 6 (A)-FIG. 7 (B) are views for describing steps of an electroless plating method, and FIG. 8 (A)-FIG. 9 (B) are views schematically illustrating a substrate in each of the steps of the electroless plating method.

As shown in FIG. 8 (A), a substrate 10 whose surface potential is a negative potential is prepared. The substrate 10 may be dipped in an alkaline solution (for example, an inorganic alkaline solution) 62 to thereby conduct an alkali washing, as indicated in FIG. 6 (A). By so doing, nonuniformity of the surface potential of the first and second areas 12 and 14 of the substrate 10 can be made uniform into a negative potential. Details of the alkali washing steps are the same as those described in the first example of the first embodiment.

As shown in FIG. 6 (B) and FIG. 8 (C), a droplet discharge method is used to provide a surface-active agent 64 in the first area 12 of the substrate 10. More specifically, droplets (of the surface-active agent 64) are discharged from a droplet discharge section 66 directly to the surface of the substrate 10 in a predetermined pattern configuration. By this, because the surface-active agent 64 can be selectively provided, and there is no need to form a mask with a resist layer or the like, the manufacturing process is simple. A droplet may include at least in part the surface-active agent 64, for example, include the surface-active agent 64 at its core, and its surface may be coated with a resin (adhesive material). Alternatively, a droplet may be formed solely from the surface-active agent 64. The droplet discharge method may be an ink jet method, or a dispenser coating method, and is not limited as long as it has a configuration to discharge droplets. According to the ink jet method, the technology that has been put in practice for ink jet printers can be applied, and ink (the surface-active agent 64) can be economically provided at a high speed without a waste. As an ink jet head, a piezoelectric type using a piezoelectric element, a bubble jet (registered trademark) type using an electro-thermal converter as an energy generation element, or the like can be used.

In the present example, the surface-active agent 64 has a property to form positive ion. As the surface-active agent 64, a cationic system surface-active agent may be used. In the present example, the surface potential of the first and second areas 12 and 14 of the substrate 10 is a negative potential, such that the use of a cationic system surface-active agent makes the surface potential of the substrate 10 to be in a neutral state or a positive potential in the first area 12, and a negative potential in the second area 14.

As shown in FIG. 7 (A) and FIG. 9 (A), a catalyst 68 is provided in the second area 14 of the substrate 10. In other words, the catalyst 68 is provided in the second area 14 that is exposed through the surface-active agent 64 on the substrate 10. The catalyst 68 is not provided in the first area 12. In the present example, the second area 14 is an area where a metal layer (wiring) is formed, and has a predetermined pattern configuration. To obtain the catalyst, the substrate 10 may be dipped in a solution including tin chloride, and then dipped in a catalyst liquid 70 including palladium chloride. Details thereof are the same as those described in the second example of the first embodiment.

Then, as shown in FIG. 7 (B) and FIG. 9 (B), a metal layer 72 is precipitated on the catalyst 68. Because the catalyst 68 is provided in the second area 14, the metal layer 72 can be formed in a pattern configuration along the second area 14. It is noted that the precipitation of a metal layer may be conducted by dipping the substrate 10 in an electroless plating liquid 74, more specifically, in a manner described above in the first example of the first embodiment.

In accordance with the present example, the surface-active agent 64 is patterned by using a droplet discharge method, and the catalyst 68 is provided while avoiding the surface-active agent 64. By this, the metal layer 72 can be deposited only to a required portion along a predetermined pattern configuration. For this reason, for example, there is no need to form a mask with a resist layer or the like, and a waste of material can be reduced, and wirings can be formed at a low cost with high accuracy, with a simple and short-time manufacturing process.

It is noted that the details described above in the aforementioned embodiment can be applied to other details of the present example.

### SECOND EXAMPLE

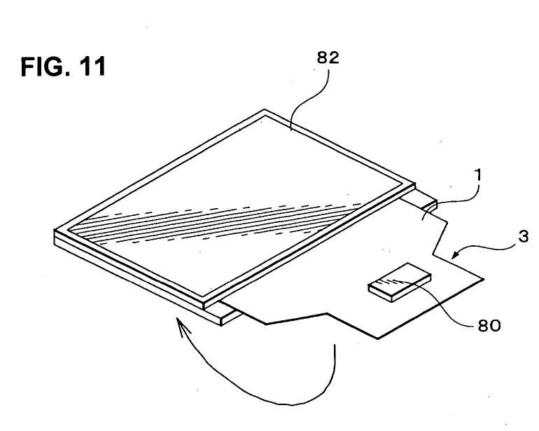

FIG. 10 (A) and FIG. 10 (B) are views illustrating a second example of the present embodiment. According to the present example, after a surface-active agent 64 has been discharged by a droplet discharge method, as indicated in FIG. 8 (A)-FIG. 8 (C), a catalyst 76 is provided on the surface-active agent 64. Because the surface-active agent 64 is provided in the first area 12, the catalyst 68 is also provided in the first area 12. The catalyst 68 is not provided in the second area 14. In the present example, the first area 12 is an area where a metal layer (wiring) is formed, and has a predetermined pattern configuration. In the present example, the (cationic system) surface-active agent 64 makes the surface potential of the substrate 10 to be in a neutral state or a positive potential in the first area 12, and a negative potential in the second area 14 because the surface of the substrate 10 is exposed. To obtain the catalyst, the substrate 10 may be dipped in a catalyst liquid including tin-palladium. Details thereof are the same as those described in the first example of the first embodiment.

Then, as shown in FIG. 10 (B), a metal layer 78 is precipitated to the catalyst 76. Because the catalyst 76 is provided on the first area 12, the metal layer 78 can be formed in a pattern configuration along the first area 12.

It is noted that the details described above in the aforementioned example can be applied to other details of the present example.

### Third Embodiment

FIG. 11 is a view for describing a method for manufacturing an electronic device in accordance with a third embodiment of the present invention, and more particularly, shows an example of an electronic device having a wiring substrate.

A metal layer (omitted in FIG. 11) having a predetermined pattern configuration is formed in a wiring substrate 1. A semiconductor chip 80 having an integrated circuit may be mounted (for example, face-down mounted) on the wiring substrate 1. The semiconductor chip 80 (integrated circuit) is electrically connected to the metal layer. In this manner, a semiconductor device 3 including the semiconductor chip 80 and the wiring substrate 1 may be manufactured. Then, the wiring substrate 1 (or, the semiconductor device 3) is electrically connected to a circuit board 82. Thus, the electronic device can be manufactured. It is noted that the wiring substrate 1 may be bent, as indicated by an arrow in FIG. 11.

When the circuit board 82 is an electrooptic panel, the electronic device is an electrooptic device. The electrooptic device may be a liquid crystal device, a plasma display device, an electroluminescence display device, or the like. In accordance with the present embodiment, a waste of material can be reduced, and wirings can be formed at a low cost with high accuracy, with a simple and short-time manufacturing process.

The present invention is not limited to the embodiments described above, and many modifications can be made. For example, the present invention may include compositions that are substantially the same as the compositions described in the embodiments (for example, a composition with the same function, method and result, or a composition with the same objects and result). Also, the present invention includes compositions in which portions not essential in the compositions described in the embodiments are replaced with others. Also, the present invention includes compositions that achieve the same functions and effects or achieve the same objects of those of the compositions described in the embodiments. Furthermore, the present invention includes compositions that include publicly known technology added to the compositions described in the embodiments.

1. A method for manufacturing a wiring substrate comprising the steps of:
(a) providing a surface-active agent in first and second areas of a substrate;
(b) irradiating a vacuum ultraviolet radiation to the second area of the substrate to thereby break down an interatomic bond in the second area of the substrate;
(c) washing the substrate to thereby remove a portion of the surface-active agent provided in the second area;
(d) providing a catalyst on an area of the surface-active agent remaining in the first area; and
(e) depositing a metal layer on the catalyst to thereby form a wiring composed of the metal layer along the first area.

2. A method for manufacturing a wiring substrate comprising the steps of:
(a) providing a surface-active agent in first and second areas of a substrate;
(b) irradiating a vacuum ultraviolet radiation to the second area of the substrate to thereby break down an interatomic bond in the second area of the substrate;
(c) washing the substrate to thereby remove a portion of the surface-active agent provided in the second area;
(d) providing a catalyst in the second area of the substrate; and
(e) depositing a metal layer on the catalyst to thereby form a wiring composed of the metal layer along the second area.

3. A method for manufacturing a wiring substrate according to claim 1, wherein the substrate has at least one of a C—C, C═C, C—F, C—H, C—Cl, C—N, C—O, N—H and O—H bond.

4. A method for manufacturing a wiring substrate according to claim 1, wherein the substrate has at least a C═C bond, and the vacuum ultraviolet radiation has at least a property that can break down the C═C bond.

5. A method for manufacturing a wiring substrate according to claim 1, wherein a light source of the vacuum ultraviolet radiation is an excimer lamp having Xe gas enclosed therein.

6. A method for manufacturing a wiring substrate, comprising the steps of
(a) providing a surface-active agent by using a droplet discharge method on a first area of a substrate having the first area and a second area;
(b) providing a catalyst on the surface-active agent; and
(c) depositing a metal layer on the catalyst to thereby form a wiring composed of the metal layer along the first area.

7. A method for manufacturing a wiring substrate, comprising the steps of:
(a) providing a surface-active agent by using a droplet discharge method on a first area of a substrate having the first area and a second area;
(b) providing a catalyst on the second area of the substrate; and
(c) depositing a metal layer on the catalyst to thereby form a wiring composed of the metal layer along the second area.

8. A method for manufacturing a wiring substrate according to claim 6, wherein the droplet discharge method is an ink jet method.

9. A method for manufacturing a wiring substrate according to claim 1, wherein a surface potential of the first and second areas of the substrate is a negative potential.

10. A method for manufacturing a wiring substrate according to claim 1, further comprising, before the step (b), the step of washing the substrate with an alkali.

11. A method for manufacturing a wiring substrate according to claim 1, wherein, in the step (a), a cationic system surface-active agent is used as the surface-active agent.

12. A method for manufacturing a wiring substrate according to claim 1, wherein, in the step of providing the catalyst, the substrate is dipped in a solution including tin chloride, and then dipped in a catalyst liquid including palladium chloride, to thereby deposit palladium as the catalyst.

13. A method for manufacturing a wiring substrate according to claim 1, wherein, in the step of providing the catalyst, the substrate is dipped in a catalyst liquid including tin-palladium to remove tin from the substrate, to thereby deposit palladium as the catalyst.

14. A method for manufacturing an electronic device, comprising: the method for manufacturing a wiring substrate according to claim 1, and further comprising the steps of mounting a semiconductor chip having an integrated circuit on the wiring substrate, and electrically connecting the wiring substrate to a circuit substrate.

15. A method for manufacturing a wiring substrate according to claim 2, wherein the substrate has at least one of a C—C, C═C, C—F, C—H, C—Cl, C—N, C—O, N—H and O—H bond.

16. A method for manufacturing a wiring substrate according to claim 2, wherein the substrate has at least a C═C bond, and the vacuum ultraviolet radiation has at least a property that can break down the C═C bond.

17. A method for manufacturing a wiring substrate according to claim 2, wherein a light source of the vacuum ultraviolet radiation is an excimer lamp having Xe gas enclosed therein.

18. A method for manufacturing a wiring substrate according to claim 7, wherein the droplet discharge method is an ink jet method.

19. A method for manufacturing a wiring substrate according to claim 2, wherein a surface potential of the first and second areas of the substrate is a negative potential.

20. A method for manufacturing a wiring substrate according to claim 2, further comprising, before the step (b), the step of washing the substrate with an alkali.

21. A method for manufacturing a wiring substrate according to claim 2, wherein, in the step (a), a cationic system surface-active agent is used as the surface-active agent.

22. A method for manufacturing a wiring substrate according to claim 2, wherein, in the step of providing the catalyst, the substrate is dipped in a solution including tin chloride, and then dipped in a catalyst liquid including palladium chloride, to thereby deposit palladium as the catalyst.

23. A method for manufacturing a wiring substrate according to claim 2, wherein, in the step of providing the catalyst, the substrate is dipped in a catalyst liquid including tin-palladium to remove tin from the substrate, to thereby deposit palladium as the catalyst.

24. A method for manufacturing an electronic device, comprising: the method for manufacturing a wiring substrate according to claim 2, and further comprising the steps of mounting a semiconductor chip having an integrated circuit on the wiring substrate, and electrically connecting the wiring substrate to a circuit substrate.

25. A method for manufacturing a wiring substrate according to claim 6, wherein a surface potential of the first and second areas of the substrate is a negative potential.

26. A method for manufacturing a wiring substrate according to claim 6, further comprising, before the step (b), the step of washing the substrate with an alkali.

27. A method for manufacturing a wiring substrate according to claim 6, wherein, in the step (a), a cationic system surface-active agent is used as the surface-active agent.

28. A method for manufacturing a wiring substrate according to claim 6, wherein, in the step of providing the catalyst, the substrate is dipped in a solution including tin chloride, and then dipped in a catalyst liquid including palladium chloride, to thereby deposit palladium as the catalyst.

29. A method for manufacturing a wiring substrate according to claim 6, wherein, in the step of providing the catalyst, the substrate is dipped in a catalyst liquid including tin-palladium to remove tin from the substrate, to thereby deposit palladium as the catalyst.

30. A method for manufacturing an electronic device, comprising: the method for manufacturing a wiring substrate according to claim 6, and further comprising the steps of mounting a semiconductor chip having an integrated circuit on the wiring substrate, and electrically connecting the wiring substrate to a circuit substrate.

31. A method for manufacturing a wiring substrate according to claim 7, wherein a surface potential of the first and second areas of the substrate is a negative potential.

32. A method for manufacturing a wiring substrate according to claim 7, further comprising, before the step (b), the step of washing the substrate with an alkali.

33. A method for manufacturing a wiring substrate according to claim 7, wherein, in the step (a), a cationic system surface-active agent is used as the surface-active agent.

34. A method for manufacturing a wiring substrate according to claim 7, wherein, in the step of providing the catalyst, the substrate is dipped in a solution including tin chloride, and then dipped in a catalyst liquid including palladium chloride, to thereby deposit palladium as the catalyst.

35. A method for manufacturing a wiring substrate according to claim 7, wherein, in the step of providing the catalyst, the substrate is dipped in a catalyst liquid including tin-palladium to remove tin from the substrate, to thereby deposit palladium as the catalyst.

36. A method for manufacturing an electronic device, comprising: the method for manufacturing a wiring substrate according to claim 7, and further comprising the steps of mounting a semiconductor chip having an integrated circuit on the wiring substrate, and electrically connecting the wiring substrate to a circuit substrate.
